(19) United States
(12) Patent Application Publication
(10) Pub. No.: US 2013/0113001 A1
(43) Pub. Date: May 9, 2013

(54) LED PACKAGE MODULE

(71) Applicant: Shu-Mei KU, Zhongli City (TW)

(72) Inventor: Kuo-Feng PENG, Zhubei City (TW)

(73) Assignee: Shu-Mei KU, Zhongli City (TW)

(21) Appl. No.: 13/667,973

(22) Filed: Nov. 2, 2012

(30) Foreign Application Priority Data
Nov. 4, 2011 (TW) 100140269

(51) Int. Cl. H01L 33/60

(52) U.S. Cl. 257/88; 257/E33.072

(57) ABSTRACT

An LED package module includes a circuit board, a metal board, a plurality of chips, a plurality of wires and a molding component. The metal board directly covers the whole upper surface of the circuit board, wherein the metal board is provided with a plurality of chip-mounting pads and a plurality of openings arranged adjacent to the chip-mounting pads so as to expose the wiring area of the circuit board. The chips are respectively arranged on each of the chip-mounting pads. The wires electrically connect chips and the wiring area of the circuit board. The molding component respectively covers each chip, wires and the wiring area.

### BACKGROUND OF THE INVENTION

1. Field of the Invention

The present invention is directed to an LED package module, particularly directed to an LED package module using a COB (chip on board) process.

2. Description of the Prior Art

LED (light-emitting diode) is provided with advantages such as being long-lasting, power-saving and highly durable; therefore, lighting apparatuses thereof have become a trend for saving energy and environmental protection and will be widely applied in the future. In general cases for high-luminescence LED lighting devices, lighting modules, usually including a plurality of LED lamps, are directly soldered on ordinary circuit boards or aluminum substrates. Additional heating dissipating elements, such as heat sink fins installed under the substrate, may be configured for improving effects in heat dissipation.

However, in addition to issues of heat dissipation, lighting collimation properties of common LED lighting devices fail to achieve wide lighting angles in comparison to 270 degrees for ordinary bulbs available at present. Hence, it is now an important goal to solve issues regarding heat dissipation and lighting collimation of LED lighting devices.

### SUMMARY OF THE INVENTION

To solve the above-mentioned problems, one objective of the present invention is directed to providing an LED package module having a metal plate covering the surface of the circuit board and dissipating heat in a directly upward manner.

One objective of the present invention is directed to providing an LED package module having a metal plate configured on the circuit board and exposing the wiring area so as to provide better optical reflection for the LED package module.

To achieve the above-mentioned objectives, an LED package module according to one embodiment of the present invention includes a circuit board, a metal board, a plurality of chips, a plurality of wires and a molding component. The metal board directly covers the whole upper surface of the circuit board, wherein the metal board is provided with a plurality of chip-mounting pads and a plurality of openings arranged adjacent to the chip-mounting pads so as to expose the wiring area of the circuit board. The chips are respectively arranged on each of the chip-mounting pads. The wires electrically connect chips and the wiring area of the circuit board. The molding component respectively covers each chip, wires and the wiring area.

Other advantages of the present invention will become apparent from the following descriptions taken in conjunction with the accompanying drawings wherein certain embodiments of the present invention are set forth by way of illustration and examples.

### BRIEF DESCRIPTION OF THE DRAWINGS

The foregoing aspects and many of the accompanying advantages of this invention will become more readily appreciated as the same becomes better understood by reference to the following detailed descriptions, when taken in conjunction with the accompanying drawings, wherein:

FIGS. 1A, 1B and 1C are schematic diagrams illustrating an LED package module according to one embodiment of the present invention;

FIGS. 2A and 2B are schematic diagrams according to one embodiment of the present invention;

FIGS. 3A and 3B are schematic diagrams according to one embodiment of the present invention;

FIGS. 4A, 4B and 4C are schematic diagrams according to one embodiment of the present invention; and

FIG. 5 is a partially enlarged view of one embodiment of the present invention.

### DESCRIPTION OF THE PREFERRED EMBODIMENT

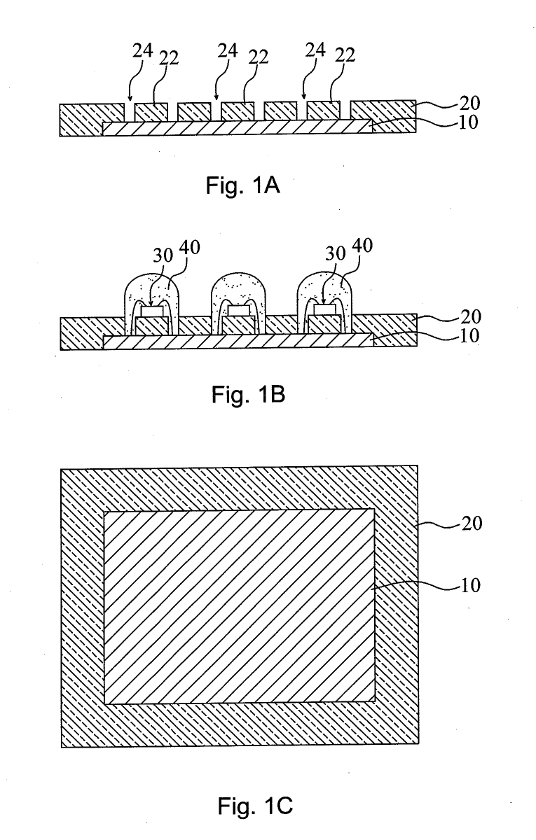

The detailed description is now illustrated as following. It is noted that the described preferred embodiments are merely illustrative instead of being used for limiting the scope of the present invention. FIGS. 1A, 1B and 1C are schematic diagrams illustrating an LED package module according to one embodiment of the present invention.

In the present embodiment, as illustrated in FIG. 1A, the LED package module includes a circuit board 10. A metal board 20 directly covers the upper surface of the circuit board 10. The metal board 20 includes a plurality of chip-mounting pads 22 and a plurality of openings 24. A wiring area at the upper surface of the circuit board 10 is then exposed because of the openings 24. The openings 24 are arranged adjacent to the chip-mounting pads 22.

Next referring to FIG. 1B, a plurality of chips 30 are respectively arranged on each of the chip-mounting pads 22. A plurality of wires (no illustrated) electrically connects chips 30 and the wiring area of the circuit board 20. Molding component 40 covers each chip 30, wires and the wiring area, respectively.

In the present embodiment, the metal board 20 directly covers the upper surface of the circuit board 10. Refer to FIG. 1C, which is a schematic diagram illustrating a backside of the present embodiment. According to FIG. 1C, the size of the metal board 20 may be larger than that of circuit board 10 in the present embodiment. The front side of the metal board 20 may provide a good reflective surface for lighting. In addition, the heat generated by the circuit board 10 and chips 30 may be dissipated via the metal board 20. Furthermore, the size of the metal board 20 may also contribute to the effect of heat dissipation.

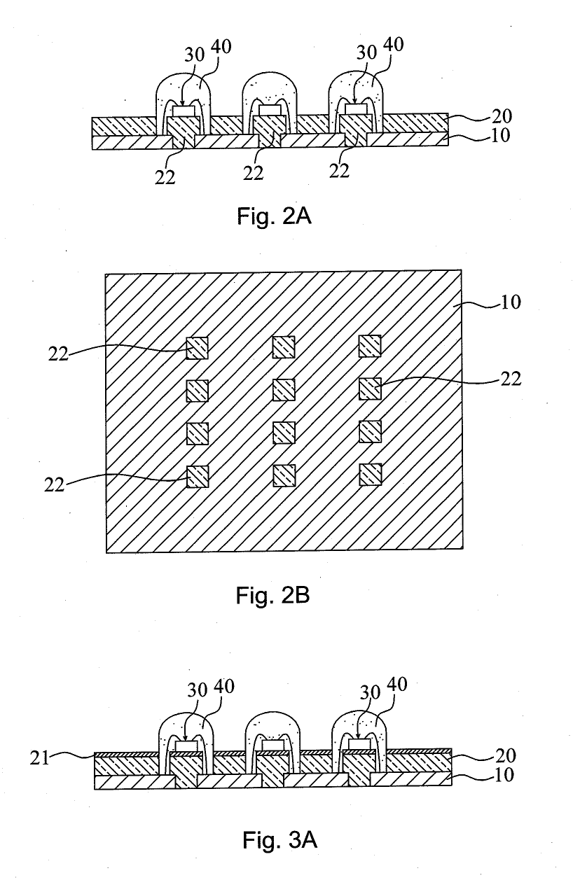

Continuing from the above description and referring to FIGS. 2A and 2B, each of said chip-mounting pads 20 of the metal board 20 has a bottom penetrating the circuit board and exposing a lower surface of each of the chip-mounting pads from the lower surface of the circuit board 10. In the present embodiment, the heat generated by the chips 30 may be dissipated via the bottom of the chip-mounting pads 22 of the metal board 20 in addition to the upper surface of the metal board 20. Referring to FIG. 2B, which is a schematic diagram illustrating a back side of the present embodiment, the size of the metal board 20 in the present embodiment may be substantially the same as that of circuit board 10. The metal board 20 may provide, besides originally available advantages, additional heat dissipation function thanks to exposure of the bottom of the chip-mounting pads 22 from the lower surface of the circuit board 10.

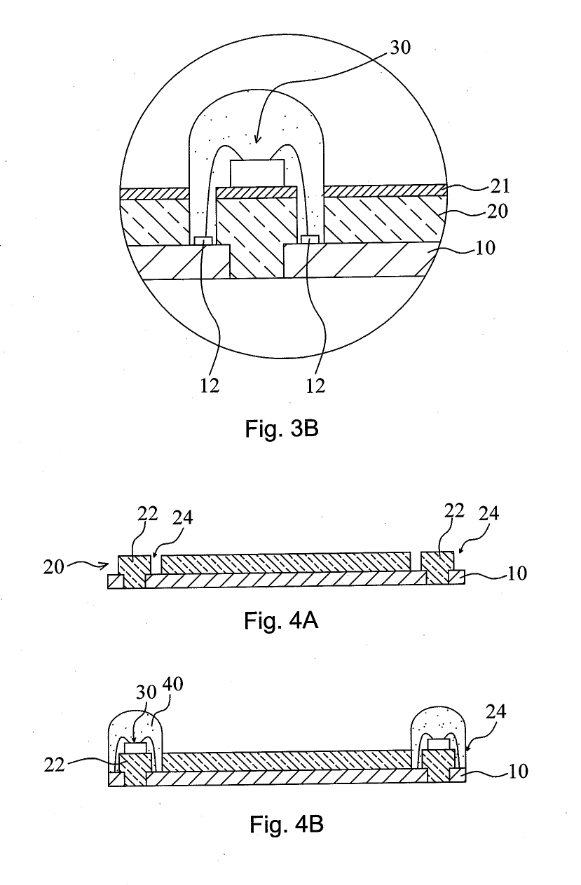

In another embodiment, as illustrated in FIG. 3A, the circuit board 10 is fully covered with the metal board 20 of the present invention; therefore, the lighting side of the LED package module is composed of the metal board 20. The metal board 20 may be made of metal materials that provide good reflective capability. In the present embodiment, a highly reflective layer 21 may be configured on the whole front surface of the metal board 20. The highly reflective layer 21 may be made of metallic silver or other highly reflective materials. Metallic silver is capable of providing excellent reflective performance and may be configured on the metal board 20 by electroplating.

FIG. 3B is a partially enlarged view of FIG. 3A. As illustrated in FIG. 3B, the wiring area is provided with a gold-plating layer 12 configured as solder pads connected with the wires. The gold-plated solder pads are resistant to oxidation and therefore prevent detachment of wires caused by oxidation so as to enhance the yield rate of package process. Furthermore, the wiring area on the circuit board 10 is located within the openings of the metal board 20. Therefore, the gold-plated solder pads are located underneath the lighting side of the chips 30 so as to prevent lowered lighting efficiency caused by light absorbance of the gold-plating layer 12.

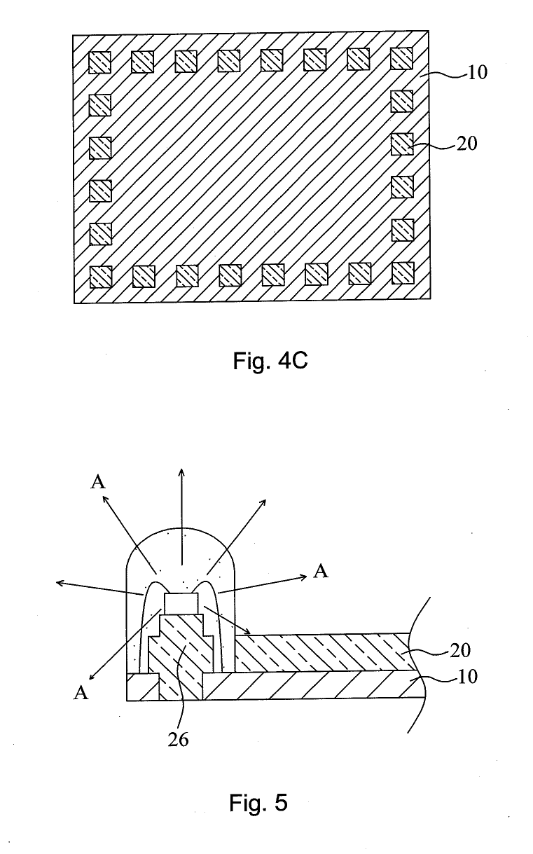

Referring to FIGS. 4A, 4B and 4C, in one embodiment, the chip-mounting pads 22 are configured at a brim region of the LED package module and the openings 24 are exposed from a brim region of the circuit board 10. As illustrated in FIG. 4A, the chip-mounting pads 22 are configured at the brim region of the circuit board 10 and the openings 24 are exposed from the brim region of the circuit board 10. As illustrated in FIG. 4B, in the present embodiment, the chip-mounting pads 22 are configured at the brim region of the LED package module. Therefore, the lighting area of the chips 30 includes the lateral face of the brim of the LED package in addition to the front side of the metal board 20. Refer to FIG. 4C, which is a schematic diagram illustrating a back side of the present embodiment. According to FIG. 4C, in the present embodiment, the bottom of the chip-mounting pad 22 of the metal board 20 is configured to penetrate the circuit board 10 such that the lower surface of the chip-mounting pads 22 may be exposed from the lower surface of the circuit board 10 so as to assist dissipation of heat generated by the chips 30.

Continuing with the above-mentioned, refer to FIG. 5, which is a partially enlarged view of one embodiment of the present invention. In this embodiment, a chip-mounting pad 26 is not only configured at a brim region of the LED package module but also configured with an uppermost part higher than a top surface of other regions of the metal board 20. In this way, the lateral lighting areas may be increased by configuring the chip 30 at the brim region relative to the whole module, and the lighting angles via an optical path A of the chip 30 may be further enhanced by configuration of the chip-mounting pad 26 and increased height of the chip 30. Therefore, the present embodiment may effectively improve the conventional drawbacks of lighting collimation for LED in comparison to 270 degrees wide lighting angles for ordinary bulbs.

It is understood that chips are mounted to chip-mounting pads with a sticking agent and electrical insulation is kept between the metal board and the circuit board. Materials and processes used therein may be commonly known for those skilled in the art and hence be abbreviated.

According the above-mentioned, the whole mounting face of the chip of the present invention may be configured with the metal board, and the surface of the metal board may be configured with highly reflective materials such as silver so as to greatly enhance the lighting efficiency of the chips. The lighting efficiency of the present invention may be enhanced since there is no any structure that would block the lighting of the chips. Package modules of the other prior arts have been provided with dam or concave cup structures at their brim regions, where reflection for lighting is necessary subsequent to lighting from the chips and hence results in optical attenuation and lowered lighting efficiency.

In the present invention, the wiring area of the circuit board is sunk under the lighting side of the chips; hence, the gold-plated solder pads at the wiring area may provide better process yield for wiring. In addition, the configuration of the sinking structure may prevent that gold-plated solder pads from absorbing light and lower lighting efficiency as a result. The chips may be directly configured on the metal board so as to greatly solve the heat dissipation issues for LED package modules. In the case of requiring additional metal boards, they may be joined with original metal boards so as to enhance lighting efficiency and life time for LED. In addition, the wires of the circuit board are embedded between the circuit board and the metal board. It would take only insulation configuration for passing high-voltage test. Processes and materials used therein may be simplified and cost for processes and materials may be lowered since components used in the structures of the present invention are simple.

To sum up, the present invention may provide better performance in optical reflection and heat dissipation for LED package modules by covering whole surface of the circuit board with a metal board to dissipate heat in a directly upward manner and covering the circuit board with the metal board and exposing only wiring areas of the circuit board.

While the invention can be subject to various modifications and alternative forms, a specific example thereof has been shown in the drawings and is herein described in detail. It should be understood, however, that the invention is not to be limited to the particular form disclosed, but on the contrary, the invention is to cover all modifications, equivalents, and alternatives falling within the spirit and scope of the appended claims.

What is claimed is:

1. An LED package module comprising:
a circuit board;
a metal board directly covering a whole upper surface of the circuit board, wherein the metal board includes a plurality of chip-mounting pads and a plurality of openings arranged adjacent to the chip-mounting pads so as to expose a wiring area of the circuit board;
a plurality of chips respectively arranged on each of the chip-mounting pads;
a plurality of wires electrically connecting chips and the wiring area of the circuit board; and
a molding component respectively covering each chip, wires and the wiring area.

2. The LED package module as claimed in claim 1, wherein each of the chip-mounting pads has a bottom penetrating the circuit board and exposing a lower surface of each of the chip-mounting pads.

3. The LED package module as claimed in claim 1, wherein an upper surface of the metal board is provided with a highly reflective layer made of metallic silver or highly reflective materials.

4. The LED package module as claimed in claim 1, wherein the chip-mounting pads are configured at a brim region of the LED package module and the openings are exposed from a brim region of the circuit board.

5. The LED package module as claimed in claim 1, wherein each of the chip-mounting pads has an uppermost part higher than a top surface of other regions of the metal board.

6. The LED package module as claimed in claim 1, wherein the wiring area is provided with a gold-plating layer configured for soldering with the wires.
